(19) United States
(12) Patent Application Publication
(10) Pub. No.: US 2026/0271723 A1
(43) Pub. Date: Sep. 10, 2026

(54) SEMICONDUCTOR ASSEMBLY HAVING A SEMICONDUCTOR ELEMENT AND A SUBSTRATE

(71) Applicant: Siemens Aktiengesellschaft, 80333 München (DE)

(72) Inventors: ALEXANDER KIESEL, Garmisch-Partenkirchen (DE); PHILIPP KNEISSL, Nürnberg (DE); EWGENIJ OCHS, Puschendorf (DE); STEFAN PFEFFERLEIN, Heroldsberg (DE); FLORIAN SCHWARZ, Gerhardshofen (DE)

(73) Assignee: Siemens Aktiengesellschaft, 80333 München (DE)

(21) Appl. No.: 19/164,990

(22) PCT Filed: Mar. 4, 2024
(86) PCT No.: PCT/EP2024/055556

§ 371 Date: Sep. 12, 2025

(30) Foreign Application Priority Data
Mar. 15, 2023 (EP) 23162093.1

(51) Int. Cl. H10W 40/70; H10D 80/20; H10W 40/00; H10W 40/20; H10W 40/22; H10W 40/25; H10W 74/10; H10W 76/05; H10W 76/15; H10W 76/42

(52) U.S. Cl. CPC H10W 40/70; H10W 40/03; H10W 40/226; H10W 40/235; H10W 40/242; H10W 40/255; H10W 74/114; H10W 76/05; H10W 76/15; H10W 76/42; H10D 80/251

(57) ABSTRACT

An assembly includes a substrate with a metallization having a first conductor structure and a second conductor structure, with the first conductor structure being arranged at least partially within the second conductor structure. An electronic component is connected to the first conductor structure. A thermally conductive housing element is designed to surround the electronic component and connected with a material bond to the second conductor structure. A thermally conductive filler material connects a cover surface and a side surface of the electronic component to the housing element.

The invention relates to an assembly having an electronic component and a substrate.

The invention further relates to a power inverter having at least one assembly of said type.

The invention also relates to a method for producing an assembly having an electronic component and a substrate.

The invention additionally relates to a use of segment strips having segments, each of which has a cavity, for producing housing elements for an assembly of said type.

Assemblies of said type are employed in a power inverter, for example. By a power inverter is to be understood for example a rectifier, a DC/AC converter, an AC/AC converter or a DC/DC converter. In a power inverter, active electronic components such as transistors and diodes, as well as passive electronic components, e. g, capacitors, resistors but also sensors, can be used. Such electronic components are typically connected to a substrate. The electrical performance, in particular the service life, of the electronic components is substantially dependent on their thermal heat dissipation capacity. For a high rate of heat flow or thermal flow, the heat dissipation time plays a critical role. Although high heat flow rates can be achieved using a fluid cooling means, the cooling solution can become very complicated and expensive, depending on application. Furthermore, heat spreader plates and heatsinks, for example, require a large amount of installation space.

Against this background, it is an object of the present invention to reduce the installation space of an assembly of said type and to provide improved heat dissipation.

This object is achieved according to the invention by means of an assembly having an electronic component and a substrate, wherein the substrate has a metallization having at least a first conductor structure and a second conductor structure, wherein the first conductor structure is arranged at least partially within the second conductor structure, wherein the electronic component is connected, in particular connected with a material bond, to the first conductor structure, wherein the electronic component is surrounded by a thermally conductive housing element that is connected with a material bond to the second conductor structure, wherein a cover surface and at least one side surface of the electronic component are connected to the housing element via a thermally conductive filler material.

The object is further achieved according to the invention by means of a power inverter having at least one assembly of the aforesaid type.

The object is also achieved according to the invention by means of a method for producing an assembly having an electronic component and a substrate, wherein the substrate has a metallization having at least a first conductor structure and a second conductor structure, wherein the first conductor structure is arranged at least partially within the second conductor structure, said method comprising the following steps: inserting the electronic component and a thermally conductive filler material into a thermally conductive housing element, wherein a cover surface and at least one side surface of the electronic component are connected to the housing element via the thermally conductive filler material, connecting the electronic component to the first conductor structure and connecting the housing element to the second conductor structure with a material bond.

The object is additionally achieved according to the invention by means of a method for producing an assembly having an electronic component and a substrate, wherein the substrate has a metallization having at least a first conductor structure and a second conductor structure, wherein the first conductor structure is arranged at least partially within the second conductor structure, said method comprising the following steps: connecting the electronic component to the first conductor structure and connecting with a material bond a thermally conductive housing element to the second conductor structure, filling the housing element with a thermally conductive, flowable filler material, wherein a cover surface and at least one side surface of the electronic component are connected to the housing element via the filler material.

The object is further achieved according to the invention by means of a use of, in particular metallic, segment strips having segments, each of which has a cavity, for producing housing elements for such an assembly, wherein the segment strips have predetermined breaking points, in particular having a perforation, between the segments.

The advantages and preferred embodiments mentioned below in relation to the assembly can be applied analogously to the power inverter, the methods and the use.

The object underlying the invention is to improve the heat dissipation of an electronic component which is connected on a substrate via an additional thermal path. As well as the heat dissipation by way of the substrate, an additional thermal path is created via a thermally conductive housing element which encloses the electronic component. The thermally conductive housing element can be produced inter alia from a metallic material, e.g. copper, aluminum or one of the alloys thereof, a thermally conductive plastic or a ceramic material. A thermal connection of the electronic component to the thermally conductive housing element is established via a thermally conductive filler material, wherein a cover surface and at least one side surface of the electronic component are connected to the housing element via the filler material. For example, the housing element has a housing inner wall which is connected to the filler material. The thermally conductive filler material may be implemented as electrically insulating or electrically conductive.

The substrate has a metallization having at least a first conductor structure and a second conductor structure, wherein the first conductor structure is arranged at least partially within the second conductor structure. For example, the second conductor structure comprises a conductor track which partially surrounds a conductor track of the first conductor structure. Such a conductor track of the second conductor structure, extending around the first conductor structure, may be Implemented inter alla as elliptical, round, rectangular or square and have at least one interruption. In particular, the second conductor structure is arranged electrically insulated from the first conductor structure. The substrate can be implemented among other things as a DCB (Direct Copper Bonded) substrate. The electronic component is connected, in particular connected with a material bond, to the first conductor structure. For example, the electronic component is connected to the first conductor structure by means of soldering, sintering or adhesive bonding. The thermally conductive housing element is connected with a material bond, e.g. by means of soldering, sintering or adhesive bonding, to the second conductor structure. Alternatively, the electronic component can be connected to the first conductor structure as a force fit by applying pressure, e.g. by means of the housing element. By means of such an arrangement exhibiting a low contact resistance, thermal losses resulting during the operation of the electronic component can be additionally dissipated to the substrate or to the environment via the thermally conductive filler material and the thermally conductive housing element. Furthermore, installation space is saved as a result of the thermally conductive housing element and the thermally conductive filler material.

A further embodiment provides that the thermally conductive filler material is flowable, at least at the time the electronic component is in operation. In particular, the thermally conductive filler material is implemented in the form of a liquid. This results in a low contact resistance and consequently very good thermal conductivity.

A further embodiment provides that the electronic component is encapsulated, In particular in a fluid-tight manner, by means of the housing element. As a result of such an encapsulation, a leakage of the thermally conductive filler material is prevented, thus simplifying maintenance and increasing service life. Furthermore, an encapsulated assembly of said type allows further housing components to be dispensed with, at least to some extent, thereby realizing an additional saving in terms of installation space.

A further embodiment provides that the thermally conductive filler material is implemented as electrically insulating. In particular, the thermally conductive filler material is realized as an inert fluid. Suitable candidates include Galden® HS 240, 3M™ Novec™ or 3M™ Fluorinert™, as well as paraffins. Inert fluids of this type can have a high dielectric strength of at least 10 kV/mm, in particular 20 kV/mm. Furthermore, using electrically insulating liquids results in a low contact resistance and very good thermal conductivity, A further embodiment provides that an intermediate space between the electronic component and the housing element is completely filled by the thermally conductive filler material. Optimized Insulation properties are achieved as a result and installation space can be saved. The contact resistance is also reduced, leading to improved heat dissipation.

A further embodiment provides that the thermally conductive filler material is implemented as electrically conductive. For example, the thermally conductive filler material comprises a liquid metal. The liquid metal may include gallium and/or indium, among others. A thermal conductivity of the filler material of at least 40 W/mk, in particular 60 W/mK, can be achieved as a result.

A further embodiment provides that the filler material is arranged electrically insulated from a contacting region of the electronic component with the substrate via an electrically insulating material. The electrically insulating material may contain silicon or a resin, among other things. Short circuits are prevented by means of such an arrangement, while a high degree of thermal conductivity is achieved.

A further embodiment provides that the electrically insulating material is at least part of a sealing element. For example, the sealing element is connected, in particular adhesively, to a housing inner wall and side surfaces of the electronic component. In particular, the filler material is encapsulated around the electronic component in a fluid-tight manner by the housing element and the sealing element. Short circuits are prevented as a result, while a high degree of thermal conductivity is achieved.

A further embodiment provides that the housing element has at least one spacer element which engages in contact with the electronic component. In particular, the at least one spacer element is connected to a housing inner surface. At least one spacer element may be embodied in the shape of a cone, a cuboid or a cylinder, etc. The electronic component is held by at least one such spacer element, thereby increasing a mechanical stability during the joining process, in particular prior to the bonding to the substrate.

A further embodiment provides that the housing element has a closable opening so that it can be filled with the thermally conductive filler material, which is implemented as flowable. The housing element can be filled particularly easily through such an opening.

A further embodiment provides that the housing element has fins, in particular at least on a side facing away from the substrate. A housing surface facing toward the environment is enlarged by means of such fins and thus provides improved heat dissipation.

The invention is described and explained in more detail below with reference to the exemplary embodiments illustrated in the figures.

It is shown in:

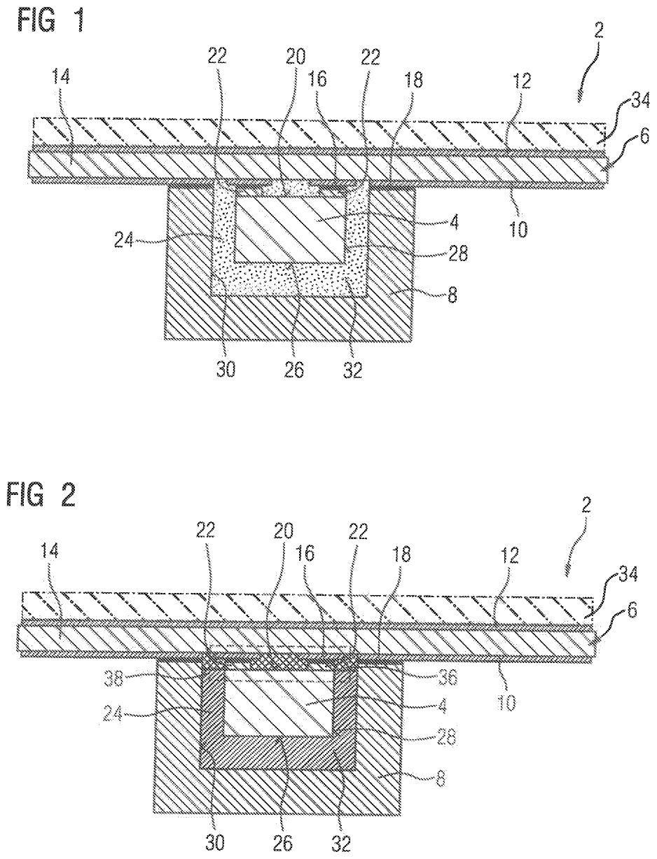

FIG. 1 a schematic sectional view of a first embodiment of an assembly,

FIG. 2 a schematic sectional view of a second embodiment of an assembly,

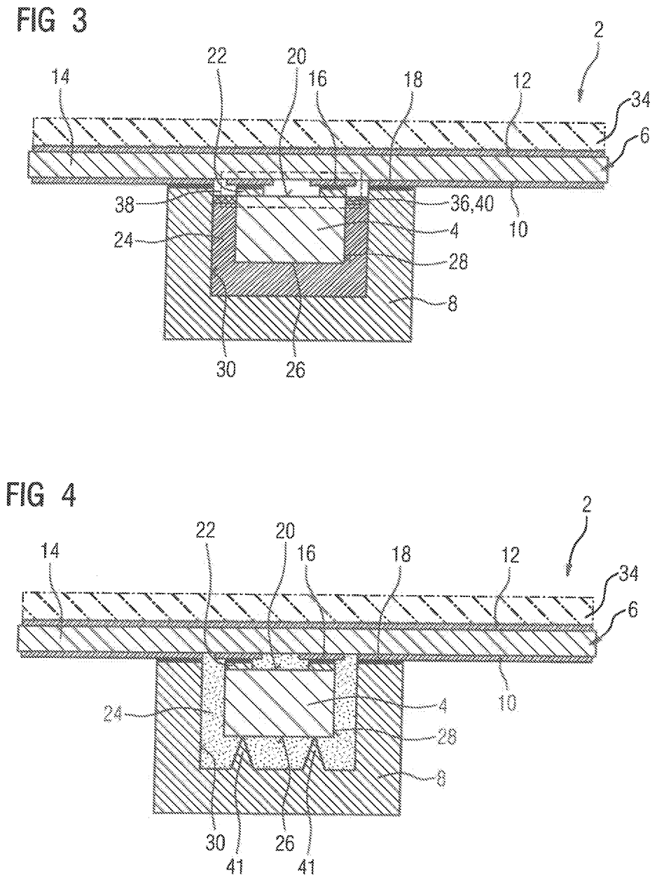

FIG. 3 a schematic sectional view of a third embodiment of an assembly,

FIG. 4 a schematic sectional view of a fourth embodiment of an assembly,

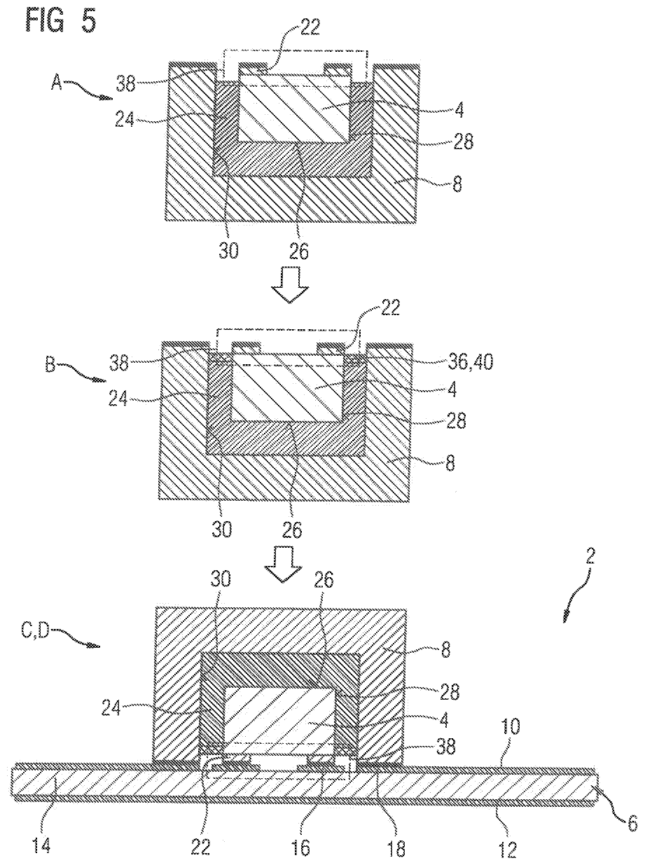

FIG. 5 a schematic illustration of a method for producing an assembly,

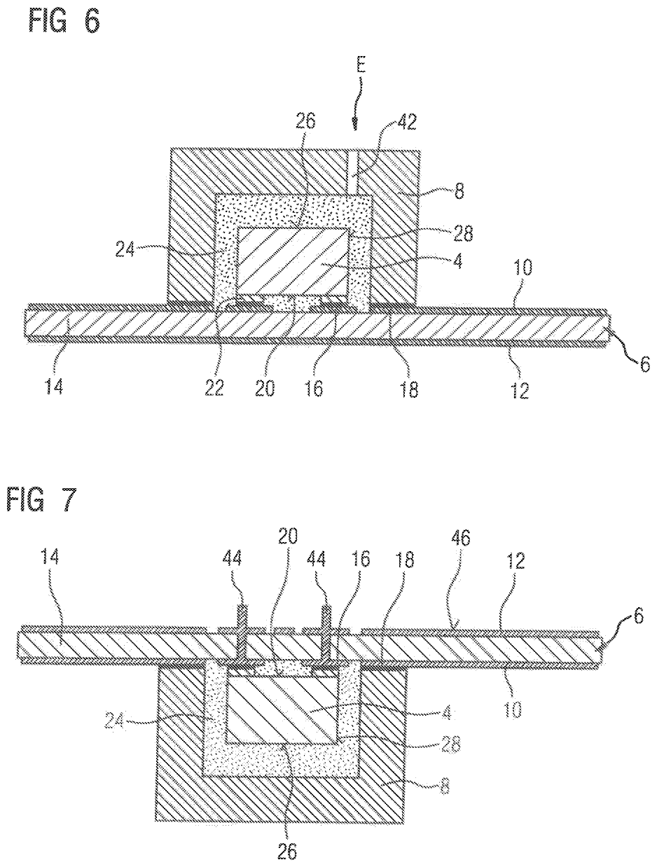

FIG. 6 a schematic sectional view of a fifth embodiment of an assembly,

FIG. 7 a schematic sectional view of a sixth embodiment of an assembly,

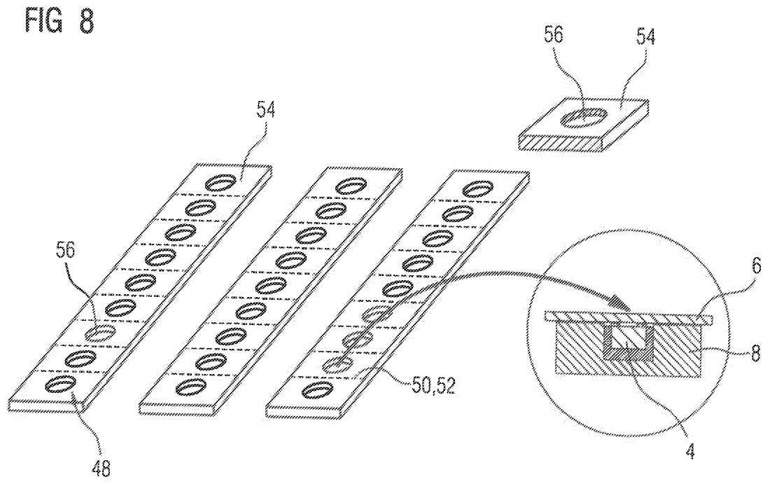

FIG. 8 a schematic illustration of segment strips for producing housing elements for an assembly,

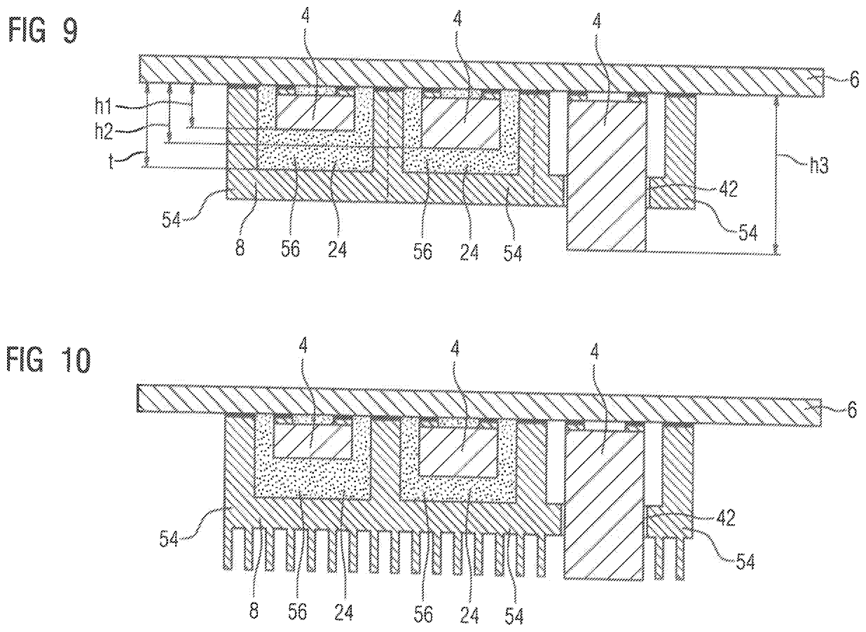

FIG. 9 a schematic sectional view of a seventh embodiment of an assembly,

FIG. 10 a schematic sectional view of an eighth embodiment of an assembly,

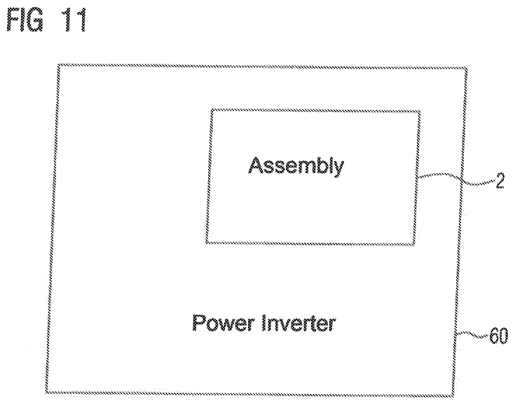

FIG. 11 a schematic illustration of a power inverter.

The exemplary embodiments explained in the following are preferred embodiments of the Invention. In the exemplary embodiments, the described components of the embodiments in each case represent individual features of the invention which are to be considered independently of one another and which also develop the invention independently of one another in each case and therefore should also be regarded individually or in another combination than that shown as part of the invention. Furthermore, the described embodiments may also be supplemented by other of the already described features of the invention.

Like reference signs have the same meaning throughout the different figures.

FIG. 1 shows a schematic sectional view of a first embodiment of an assembly 2, which is implemented as a power assembly and comprises an electronic component 4, a substrate 6 and a thermally conductive housing element 8. The electronic component 4 is implemented by way of example as a lateral power semiconductor, in particular having a wide bandgap. Such power semiconductors can be realized for example in silicon carbide or gallium nitride technology. Alternatively, the electronic component 4 can be implemented inter alla as a different power semiconductor, such as, for example, as an IGBT or a vertical SIC MOSFET, as a diode or as a passive component, e.g. as a shunt resistor. The substrate 6 has a metallization 10 on a side facing toward the electronic component 4 and a further metallization 12 on a side facing away from the electronic component 4. The metallizations are mechanically and thermally conductively connected via a dielectric material layer 14, which may contain aluminum oxide or aluminum nitride, for example. In particular, the substrate 6 is implemented as a DCB (Direct Copper Bonded) substrate. The metallization 10 comprises a first conductor structure 16 and a second conductor structure 18 arranged electrically insulated from the first conductor structure 16, wherein the first conductor structure 16 is arranged at least partially within the second conductor structure 18. On a base surface 20, the electronic component 4 has contacting elements 22, for example pins, via which the electronic component 4 is connected with a material bond, for example via a soldered or sintered joint, to the first conductor structure 16 of the metallization 10. The electronic component 4 implemented as a power semiconductor can be connected to the substrate 6 in a package or “bare die”.

The electronic component 4 is arranged in the thermally conductive housing element 8 and thus surrounded by the latter. The thermally conductive housing element 8 is produced for example from a metallic material, e.g. copper, aluminum or one of their alloys, a thermally conductive plastic or a ceramic material. Furthermore, the housing 8 is connected with a material bond, for example adhesively, to the second conductor structure 18 of the metallization 10. The adhesive bond is established by means of a thermally conductive glue. If the housing 8 is fabricated from a metallic material, at least in the region where it makes contact with the metallization 10, the material-bonded connection can alternatively be produced by soldering or sintering. The electronic component 4 is encapsulated, in particular in a fluid-tight manner, by means of the material-bonded connection of the housing element 8 to the second conductor structure 16.

A thermally conductive filler material 24 is arranged in the thermally conductive housing element 8. The thermally conductive filler material 24, which is flowable at least at the time the electronic component 4 is in operation, arranged. In FIG. 1, the thermally conductive filler material 24 is implemented as an electrically insulating inert fluid. Examples of such inert fluids include inter alia Galden® HS 240, 3M™ Novec™, 3M™ Fluorinert™. In addition or alternatively, the thermally conductive filler material 24 may contain a paraffin. In particular, the thermally conductive filler material 24 has a dielectric strength of at least 10 kV/mm. In addition to the base surface 20, the electronic component 4, implemented for example as substantially cuboidal, has a cover surface 26 and side surfaces 28, wherein both the cover surface 26 and the side surfaces 28 of the electronic component 4 are in full contact with the thermally conductive filler material 24 and are connected via the thermally conductive filler material 24 to a housing inner wall 30 of the housing element 8. By way of example, in FIG. 1, an intermediate space 32 between the electronic component 4 and the housing element 8 is completely filled by the thermally conductive and electrically insulating filler material 24. In this way, thermal losses resulting during the operation of the electronic component 4 can be additionally dissipated to the environment via the thermally conductive filler material 24 and the thermally conductive housing element 8. In addition, the further metallization 12 of the substrate 6 can be connected over its surface to a heatsink 34, in particular a cooling element. The thermal losses resulting during the operation of the electronic component 4 can therefore be dissipated via the thermally conductive filler material 24, the thermally conductive housing element 8 and the substrate 6 to the heatsink 34 connected over its surface to the further metallization 12 of the substrate 6.

FIG. 2 shows a schematic sectional view of a second embodiment of an assembly 2, wherein the thermally conductive filler material 24 is implemented as electrically conductive. Liquid metal, for example, is used as an electrically and thermally conductive filler material 24. In order to avoid short circuits, the filler material 24 is arranged electrically insulated from a contacting region 38 of the electronic component 4 with the substrate 6 via an electrically insulating material 36. The electrically insulating material 36 may contain inter alia underfill, plastic or silicon. The further embodiment of the assembly 2 in FIG. 2 corresponds to the embodiment in FIG. 1.

FIG. 3 shows a schematic sectional view of a third embodiment of an assembly 2. An electrically insulating material 36 is implemented as a sealing element 40 which prevents the electrically and thermally conductive filler material 24, which is flowable at least at the time the electronic component 4 is in operation, from making contact with the contacting elements 22 of the electronic component 4. For example, the sealing element 40 is connected, in particular adhesively, to the housing inner wall 30 and the side surfaces 28 of the electronic component 4. The filler material 24 is encapsulated in a fluid-tight manner around the electronic component 4 by means of the housing element 8 and the sealing element 40. The further embodiment of the assembly 2 in FIG. 3 corresponds to the embodiment in FIG. 2.

FIG. 4 shows a schematic sectional view of a fourth embodiment of an assembly 2, wherein the housing element 8 has spacer elements 41 on the housing inner wall 30 which make contact with the electronic component 4. The spacer elements 41, which are designed for example in the shape of a cone or alternatively in the shape of a cuboid or cylinder, hold the electronic component 4 and increase the mechanical stability during the joining process, in particular prior to the connection to the substrate 6. The further embodiment of the assembly 2 in FIG. 4 corresponds to the embodiment in FIG. 1.

FIG. 5 shows a schematic Illustration of a method for producing an assembly 2. The method comprises the following steps:

Inserting A an electronic component 4 and a thermally conductive filler material 24 into a thermally conductive housing element 8, wherein a cover surface 26 and the side surfaces 28 of the electronic component 4 are connected to the housing element 8 via the thermally conductive filler material 24. The thermally conductive filler material 24 used is implemented as electrically conductive and flowable at least at the time the electronic component 4 is in operation. Liquid metal is used as the electrically and thermally conductive filler material 24, for example. The electronic component 4 is Inserted in such a way that the contacting region 38 of the electronic component 4 with the contacting elements 22 is not in contact with the liquid metal.

In a further step, the liquid metal is sealed B against the contacting region 38 of the electronic component 4 by means of a sealing element 40 containing an electrically insulating material 36.

In a further step, the electronic component 4 is connected C to the first conductor structure 16 of the metallization 10 of the substrate 6 and the housing element 8 is connected with a material bond D to the second conductor structure 18 of the metallization 10 of the substrate 6. The connection C and the materially-bonded connection D can be accomplished by soldering, sintering or adhesively, e.g. by means of an electrically conductive glue. Alternatively, the connection C of the electronic component 4 can be achieved by application of pressure. For example, elastic connecting elements such as springs or brackets can be used for applying pressure. The further embodiment of the assembly 2 in FIG. 5 corresponds to the embodiment in FIG. 3.

FIG. 6 shows a schematic sectional view of a fifth embodiment of an assembly 2, wherein the thermally conductive housing element 8 is filled E with a thermally conductive flowable filler material 24 after the electronic component 4 is connected C to the first conductor structure 16 and the thermally conductive housing element 8 is connected with a material bond D to the second conductor structure 18 through an opening 42. After the opening 42 has been closed, the electronic component 4 is encapsulated, in particular in a fluid-tight manner. The further embodiment of the assembly 2 in FIG. 6 corresponds to the embodiment in FIG. 1.

FIG. 7 shows a schematic sectional view of a sixth embodiment of an assembly 2. The first conductor structure 16 of the metallization 10 is guided by way of vias 44 to a side 46 of the substrate 6 facing away from the electronic component 4. The further embodiment of the assembly 2 in FIG. 7 corresponds to the embodiment in FIG. 1.

FIG. 8 shows a schematic illustration of, for example metallic, segment strips 48 for producing housing elements 8 for an assembly 2, wherein the segment strips 48 have predetermined breaking points 50, for example having a perforation 52, for producing housing elements 8 from the segments. A cavity 56 for accommodating an electronic component 4 is provided in each of the segments 54 of the segment strips 48.

FIG. 9 shows a schematic sectional view of a seventh embodiment of an assembly 2, wherein the housing element 8 is produced by way of example from three segments 54, each of which has a cavity 56. Electronic components 4 of different heights h1, h2, h3 are arranged in the cavities 56. Different heights h1, h2 of the electronic components 4, which are implemented e.g. as power semiconductors, are evened out by the thermally conductive filler material 24 provided the height h1, h2 does not exceed a deptht of the cavity 56. If an electronic component 4, e.g. a passive component such as a capacitor, having a height h3 exceeds the depth t of the cavity 56, an opening 42 can be inserted such that the electronic component 4 protrudes at a height h3 above the housing element 8.

FIG. 10 shows a schematic sectional view of an eighth embodiment of an assembly 2, wherein the housing element 8 has fins 58 on a side facing away from the substrate 6, which fins 58 Increase the size of the housing surface toward the environment and thus provide improved heat dissipation.

FIG. 11 shows a schematic illustration of a power inverter 60 which comprises an assembly 2, for example.

To sum up, the invention relates to an assembly 2 having an electronic component 4 and a substrate 6. In order to reduce the installation space of such an assembly 2 and to provide improved heat dissipation, it is proposed that the substrate 6 has a metallization 10 having at least a first conductor structure 16 and a second conductor structure 18, wherein the first conductor structure 16 is arranged at least partially within the second conductor structure 18, wherein the electronic component 4 is connected, in particular connected with a material bond, to the first conductor structure 16, wherein the electronic component 4 is surrounded by a thermally conductive housing element 8 that is connected with a material bond to the second conductor structure 18, wherein a cover surface 26 and at least one side surface 28 of the electronic component 4 are connected to the housing element 8 via a thermally conductive filler material 24.

1-19. (canceled)

20. An assembly, comprising:
a substrate comprising a metallization having a first conductor structure and a second conductor structure, with the first conductor structure being arranged at least partially within the second conductor structure;
an electronic component connected to the first conductor structure;
a thermally conductive housing element designed to surround the electronic component and connected with a material bond to the second conductor structure; and
a thermally conductive filler material via which a cover surface and a side surface of the electronic component are connected to the housing element.

21. The assembly of claim 20, wherein the electronic component is connected with a material bond to the first conductor structure,

22. The assembly of claim 20, wherein the thermally conductive filler material is flowable at least at a time when the electronic component is in operation.

23. The assembly of claim 20, wherein the electronic component is encapsulated, in particular in a fluid-tight manner, by the housing element.

24. The assembly of claim 20, wherein the thermally conductive filler material is designed to be electrically Insulating.

25. The assembly of claim 24, wherein the electronic component and the housing element define there between an intermediate space which is filled completely by the thermally conductive filler material.

26. The assembly of claim 20, wherein the thermally conductive filler material is designed to be electrically conductive.

27. The assembly of claim 26, further comprising an electrically insulating material arranged to electrically insulate the thermally filler material from a contacting region of the electronic component with the substrate,

28. The assembly of claim 27, wherein the electrically insulating material is at least part of a sealing element.

29. The assembly of claim 20, wherein the housing element comprises a spacer element designed to make contact with the electronic component.

30. The assembly of claim 20, wherein the housing element comprises a closable opening to enable the housing element to be filled with the thermally conductive filler material, when the thermally conductive filler material is flowable.

31. The assembly of claim 20, wherein the housing element comprises fins, in particular on a side facing away from the substrate.

32. A power inverter, comprising the assembly of claim 20.

33. A method for producing an assembly with an electronic component and a substrate which comprises a metallization having a first conductor structure and a second conductor structure within which the first conductor structure is at least partially arranged, the method comprising:
inserting the electronic component and a thermally conductive filler material into a thermally conductive housing element such that a cover surface and a side surface of the electronic component is connected to the housing element via the thermally conductive filler material;
connecting the electronic component to the first conductor structure of the metallization of the substrate; and
connecting with a material bond the housing element to the second conductor structure of the metallization of the substrate.

34. The method of claim 33, wherein the thermally conductive filler material is flowable at least at a time when the electronic component is in operation.

35. The method of claim 33, further comprising encapsulating the electronic component, in particular in a fluid-tight manner, as the housing element is connected to the second conductor structure by the material bond.

36. The method of claim 33, further comprising:
designing the thermally conductive filler material to be electrically conductive; and
arranging the thermally conductive filler material electrically insulated from a contacting region of the electronic component with the substrate via an electrically insulating material.

37. The method of claim 33, further comprising sealing the thermally conductive filler material against a contacting region of the electronic component after the electronic component and the thermally conductive filler material have been inserted into the thermally conductive housing element.

38. A method for producing an assembly with an electronic component and a substrate which comprises a metallization having a first conductor structure and a second conductor structure within which the first conductor structure is at least partially arranged, the method comprising:
connecting the electronic component to the first conductor structure of the metallization of the substrate;
connecting with a material bond a thermally conductive housing element to the second conductor structure of the metallization of the substrate; and
filling the thermally conductive housing element with a thermally conductive flowable filler material such that a cover surface and a side surface of the electronic component are connected to the housing element via the thermally conductive flowable filler material.

39. A segment strip, in particular metallic segment strip, for use in a production of a housing element for the assembly of claim 20, the segment strip comprising:
segments, each of which having a cavity; and
predetermined breaking points, in particular in form of a perforation, between the segments.
